(19) United States
(12) Patent Application Publication
(10) Pub. No.: US 2024/0345469 A1
(43) Pub. Date: Oct. 17, 2024

(54) PHOTOMASK STRUCTURE

(71) Applicant: United Microelectronics Corp., Hsinchu (TW)

(72) Inventors: Chia-Chen Sun, Kaohsiung City (TW); En-Chiuan Liou, Tainan City (TW); Song-Yi Lin, Tainan City (TW)

(73) Assignee: United Microelectronics Corp., Hsinchu (TW)

(21) Appl. No.: 18/308,670

(22) Filed: Apr. 27, 2023

(30) Foreign Application Priority Data
Apr. 12, 2023 (TW) 112113722

(51) Int. Cl. G03F 1/38

(52) U.S. Cl. CPC G03F 1/38; H01L 21/0273

(57) ABSTRACT

A photomask structure including a layout pattern, a first L-type assist pattern, and a second L-type assist pattern is provided. An end portion of the layout pattern includes a first edge, a second edge, and a third edge. The second edge is connected to one end of the first edge, and the third edge is connected to another end of the first edge. The first L-type assist pattern is located between the second L-type assist pattern and the first edge. The layout pattern, the first L-type assist pattern, and the second L-type assist pattern are separated from each other. The first L-type assist pattern surrounds the first edge and the second edge. The second L-type assist pattern surrounds the first edge and the third edge.

### CROSS-REFERENCE TO RELATED APPLICATION

This application claims the priority benefit of Taiwan application serial no. 112113722, filed on Apr. 12, 2023. The entirety of the above-mentioned patent application is hereby incorporated by reference herein and made a part of this specification.

### BACKGROUND

### Technical Field

The disclosure relates to a photomask structure, and in particular relates to a photomask structure including assist patterns.

### Description of Related Art

In a semiconductor manufacturing process, lithography technology plays a pivotal role. However, the photoresist pattern formed by the lithography process often has corner rounding defects. Therefore, how to develop a mask that may reduce corner rounding is an ongoing goal.

### SUMMARY

A photomask structure is provided in this disclosure, in which the photomask structure may effectively reduce the corner rounding of the photoresist pattern formed by the lithography process.

A photomask structure including a layout pattern, a first L-type assist pattern, and a second L-type assist pattern is provided in this disclosure. An end portion of the layout pattern includes a first edge, a second edge, and a third edge. The second edge is connected to one end of the first edge, and the third edge is connected to another end of the first edge. The first L-type assist pattern is located between the second L-type assist pattern and the first edge. The layout pattern, the first L-type assist pattern, and the second L-type assist pattern are separated from each other. The first L-type assist pattern surrounds the first edge and the second edge. The second L-type assist pattern surrounds the first edge and the third edge.

According to an embodiment of the disclosure, in the photomask structure, the first L-type assist pattern may include a fourth edge and a fifth edge opposite to each other. The fourth edge may be adjacent to the second edge. The fifth edge may be adjacent to the third edge. The second L-type assist pattern may include a sixth edge and a seventh edge opposite to each other. The sixth edge may be adjacent to the second edge. The seventh edge may be adjacent to the third edge.

According to an embodiment of the disclosure, in the photomask structure, the fourth edge may be flush with the sixth edge.

According to an embodiment of the disclosure, in the photomask structure, the fifth edge may be flush with the third edge.

According to an embodiment of the disclosure, in the photomask structure, the first L-type assist pattern includes a first main portion and a first extension portion. The first main portion is on one side of the first edge. The first extension portion is connected to one end of the first main portion and is located on one side of the second edge. The second L-type assist pattern includes a second main portion and a second extension portion. The second main portion is on one side of the first edge. The first main portion is between the second main portion and the first edge. The second extension portion is connected to one end of the second main portion and is located on one side of the third edge.

According to an embodiment of the disclosure, in the photomask structure, a width of the first main portion and a width of the second main portion may be the same.

According to an embodiment of the disclosure, in the photomask structure, a width of the first main portion and a width of the second main portion may be different.

According to an embodiment of the disclosure, in the photomask structure, a width of the first extension portion and a width of the second extension portion may be the same.

According to an embodiment of the disclosure, in the photomask structure, a width of the first extension portion and a width of the second extension portion may be different.

According to an embodiment of the disclosure, in the photomask structure, a width of the first main portion and a width of the first extension portion may be the same.

According to an embodiment of the disclosure, in the photomask structure, a width of the first main portion and a width of the first extension portion may be different.

According to an embodiment of the disclosure, in the photomask structure, a width of the second main portion and a width of the second extension portion may be the same.

According to an embodiment of the disclosure, in the photomask structure, a width of the second main portion and a width of the second extension portion may be different.

According to an embodiment of the disclosure, in the photomask structure, the layout pattern may extend in a first direction. The first edge may be perpendicular to the first direction, and the second edge and the third edge may be parallel to the first direction.

According to an embodiment of the disclosure, in the photomask structure, the first main portion may extend in a second direction. The second direction may be perpendicular to the first direction.

According to an embodiment of the disclosure, in the photomask structure, the first extension portion may extend in a second direction. The second direction may be parallel to the first direction.

According to an embodiment of the disclosure, in the photomask structure, the second main portion may extend in a second direction. The second direction may be perpendicular to the first direction.

According to an embodiment of the disclosure, in the photomask structure, the second extension portion may extend in a second direction. The second direction may be parallel to the first direction.

According to an embodiment of the disclosure, in the photomask structure, a minimum spacing between the first L-type assist pattern and the layout pattern may be greater than or equal to a minimum spacing specified by a design rule. A minimum spacing between the second L-type assist pattern and the layout pattern may be greater than or equal to the minimum spacing specified by the design rule.

According to an embodiment of the disclosure, in the photomask structure, a minimum spacing between the first L-type assist pattern and the second L-type assist pattern may be greater than or equal to a minimum spacing specified by a design rule.

Based on the above, in the photomask structure provided by the disclosure, the end portion of the layout pattern includes a first edge, a second edge, and a third edge. The second edge is connected to one end of the first edge, and the third edge is connected to another end of the first edge. The first L-type assist pattern is located between the second L-type assist pattern and the first edge. The layout pattern, the first L-type assist pattern, and the second L-type assist pattern are separated from each other. The first L-type assist pattern surrounds the first edge and the second edge. The second L-type assist pattern surrounds the first edge and the third edge. Therefore, when the photomask structure provided by the disclosure is used for the lithography process, the pattern fidelity of the lithography process may be improved. In this way, when the photomask structure provided by the disclosure is used for the lithography process, the corner rounding of the photoresist pattern formed by the lithography process may be effectively reduced, and the process window of the semiconductor manufacturing process and the reliability of the semiconductor device may be improved.

In order to make the above-mentioned features and advantages of the disclosure comprehensible, embodiments accompanied with drawings are described in detail below.

### BRIEF DESCRIPTION OF THE DRAWINGS

FIG. 1 is a schematic diagram of a photomask structure according to some embodiments of the disclosure.

FIG. 2 is a schematic diagram of a photomask structure according to other embodiments of the disclosure.

### DETAILED DESCRIPTION OF DISCLOSED EMBODIMENTS

The following examples are described in detail with the accompanying drawings, but the provided examples are not intended to limit the scope of the disclosure. In order to facilitate understanding, the same components in the following description are described with the same symbols. In addition, the drawings are for illustrative purposes only and are not drawn in full scale. In fact, the dimensions of the various features may be arbitrarily increased or reduced for clarity of discussion.

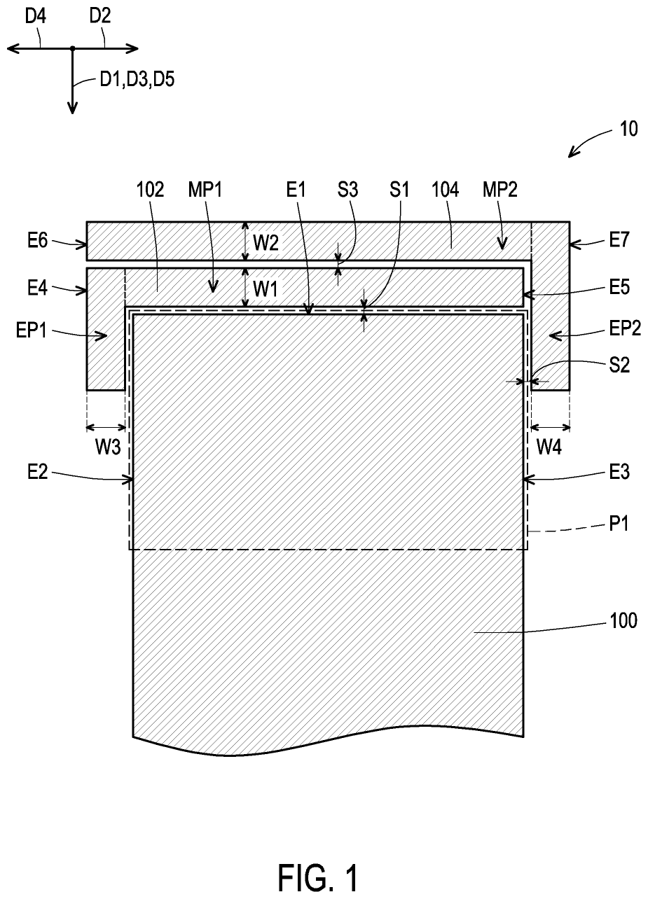

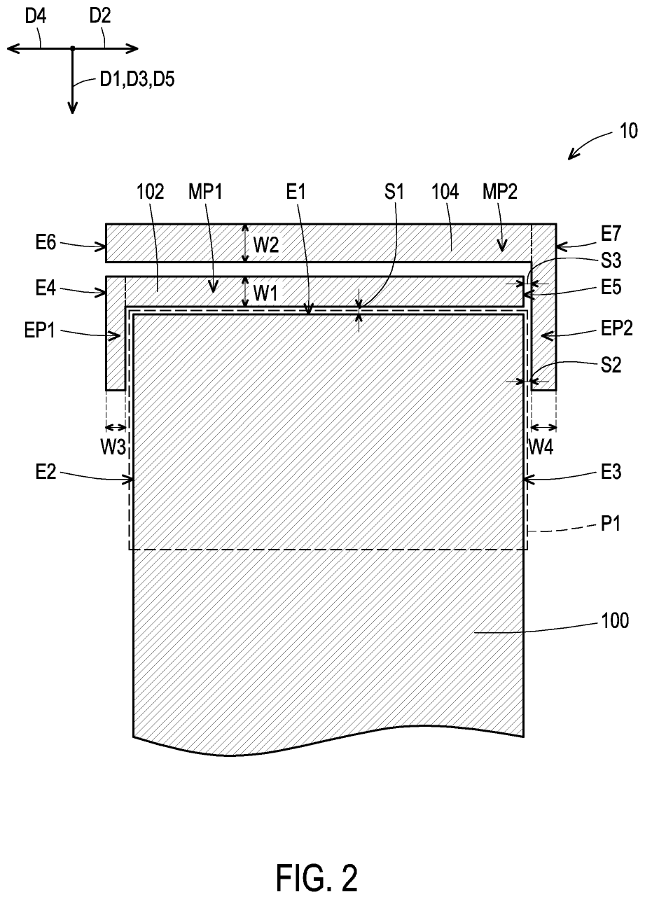

FIG. 1 is a schematic diagram of a photomask structure according to some embodiments of the disclosure. FIG. 2 is a schematic diagram of a photomask structure according to other embodiments of the disclosure.

Referring to FIG. 1, the photomask structure 10 includes a layout pattern 100, an L-type assist pattern 102, and an L-type assist pattern 104. The L-type assist pattern 102 is located between the L-type assist pattern 104 and the first edge E1. In some embodiments, the mask structure 10 may be a binary mask or a phase shift mask (PSM), but the disclosure is not limited thereto. The layout pattern 100 may be a main pattern (e.g., a wire pattern, etc.) on the photomask structure 10. In addition, the shape of the layout pattern 100 may be determined according to product design, and is not limited to the shape shown in FIG. 1.

The layout pattern 100, the L-type assist pattern 102, and the L-type assist pattern 104 are separated from each other. The minimum spacing S1 between the L-type assist pattern 102 and the layout pattern 100 may be greater than or equal to the minimum spacing specified by the design rule. The minimum spacing S2 between the L-type assist pattern 104 and the layout pattern 100 may be greater than or equal to the minimum spacing specified by the design rule. The minimum spacing S3 between the L-type assist pattern 102 and the L-type assist pattern 104 may be greater than or equal to the minimum spacing specified by the design rule. As long as the minimum spacing S1, the minimum spacing S2, and the minimum spacing S3 are greater than or equal to the minimum spacing specified by the design rule, the minimum spacing S1, the minimum spacing S2, and the minimum spacing S3 may be adjusted according to design requirements.

The end portion P1 of the layout pattern 100 includes a first edge E1, a second edge E2, and a third edge E3. The second edge E2 is connected to one end of the first edge E1, and the third edge E3 is connected to the other end of the first edge E1. The L-type assist pattern 102 surrounds the first edge E1 and the second edge E2. The L-type assist pattern 104 surrounds the first edge E1 and the third edge E3. Therefore, when the photomask structure 10 is used for the lithography process, the pattern fidelity of the lithography process may be improved.

In some embodiments, the L-type assist pattern 102 may include a fourth edge E4 and a fifth edge E5 opposite to each other. The fourth edge E4 may be adjacent to the second edge E2. The fifth edge E5 may be adjacent to the third edge E3. In some embodiments, the L-type assist pattern 104 may include a sixth edge E6 and a seventh edge E7 opposite to each other. The sixth edge E6 may be adjacent to the second edge E2. The seventh edge E7 may be adjacent to the third edge E3. In some embodiments, the fourth edge E4 may be flush with the sixth edge E6. In some embodiments, the fifth edge E5 may be flush with the third edge E3.

In some embodiments, the L-type assist pattern 102 includes a main portion MP1 and an extension portion EP1. The main portion MP1 is located on one side of the first edge E1. The extension portion EP1 is connected to one end of the main portion MP1 and is located on one side of the second edge E2. In some embodiments, the L-type assist pattern 104 includes a main portion MP2 and an extension portion EP2. The main portion MP2 is located on one side of the first edge E1. The main portion MP1 is located between the main portion MP2 and the first edge E1. The extension portion EP2 is connected to one end of the main portion MP2 and is located on one side of the third edge E3.

In some embodiments, the layout pattern 100 may extend in the direction D1. In some embodiments, the first edge E1 may be perpendicular to the direction D1, and the second edge E2 and the third edge E3 may be parallel to the direction D1. In some embodiments, the main portion MP1 may extend in the direction D2. In some embodiments, the direction D2 may be perpendicular to the direction D1. In some embodiments, the extension portion EP1 may extend in the direction D3. In some embodiments, the direction D3 may be parallel to the direction D1.

In some embodiments, the main portion MP2 may extend in the direction D4. In some embodiments, the direction D4 may be perpendicular to the direction D1. In some embodiments, the extension portion EP2 may extend in the direction D5. In some embodiments, the direction D5 may be parallel to the direction D1.

In some embodiments, as shown in FIG. 1, the width W1 of the main portion MP1 and the width W2 of the main portion MP2 may be the same, but the disclosure is not limited thereto. In other embodiments, as shown in FIG. 2, the width W1 of the main portion MP1 and the width W2 of the main portion MP2 may be different. For example, in FIG. 2, the width W1 of the main portion MP1 may be less than the width W2 of the main portion MP2, but the disclosure is not limited thereto. In other embodiments, although not shown in the figure, the width W1 of the main portion MP1 may be greater than the width W2 of the main portion MP2.

In some embodiments, as shown in FIG. 1, the width W3 of the extension portion EP1 and the width W4 of the extension portion EP2 may be the same, but the disclosure is not limited thereto. In some other embodiments, as shown in FIG. 2, the width W3 of the extension portion EP1 and the width W4 of the extension portion EP2 may be different. For example, in FIG. 2, the width W3 of the extension portion EP1 may be less than the width W4 of the extension portion EP2, but the disclosure is not limited thereto. In other embodiments, although not shown in the figures, the width W3 of the extension portion EP1 may be greater than the width W4 of the extension portion EP2.

In some embodiments, as shown in FIG. 1, the width W1 of the main portion MP1 and the width W3 of the extension portion EP1 may be the same, but the disclosure is not limited thereto. In other embodiments, as shown in FIG. 2, the width W1 of the main portion MP1 and the width W3 of the extension portion EP1 may be different. For example, in FIG. 2, the width W1 of the main portion MP1 may be greater than the width W3 of the extension portion EP1, but the disclosure is not limited thereto. In other embodiments, although not shown in the figure, the width W1 of the main portion MP1 may be less than the width W3 of the extension portion EP1.

In some embodiments, as shown in FIG. 1, the width W2 of the main portion MP2 and the width W4 of the extension portion EP2 may be the same, but the disclosure is not limited thereto. In other embodiments, as shown in FIG. 2, the width W2 of the main portion MP2 and the width W4 of the extension portion EP2 may be different. For example, in FIG. 2, the width W2 of the main portion MP2 may be greater than the width W4 of the extension portion EP2, but the disclosure is not limited thereto. In other embodiments, although not shown in the figure, the width W2 of the main portion MP2 may be less than the width W4 of the extension portion EP2.

In addition, the width W1 of the main portion MP1, the width W2 of the main portion MP2, the width W3 of the extension portion EP1, and the width W4 of the extension portion EP2 may be optimized, thereby further improving the pattern fidelity of the lithography process. In addition, in FIG. 1 and FIG. 2, the same or similar components are denoted by the same reference numerals, and descriptions thereof are omitted.

In some embodiments, when the photomask structure 10 is a binary mask, the layout pattern 100, the L-type assist pattern 102, and the L-type assist pattern 104 may be opaque patterns on the binary mask. In other embodiments, when the photomask structure 10 is a binary mask, the layout pattern 100, the L-type assist pattern 102, and the L-type assist pattern 104 may be light-transmitting patterns on the binary mask. In other embodiments, when the photomask structure 10 is a phase shift mask, the layout pattern 100, the L-type assist pattern 102, and the L-type assist pattern 104 may be phase shift patterns on the phase shift mask. In other embodiments, when the photomask structure 10 is a phase shift mask, the layout pattern 100, the L-type assist pattern 102, and the L-type assist pattern 104 may be light-transmitting patterns on the phase shift mask.

Based on the above embodiments, it may be seen that in the photomask structure 10, the end portion P1 of the layout pattern 100 includes a first edge E1, a second edge E2, and a third edge E3. The second edge E2 is connected to one end of the first edge E1, and the third edge E3 is connected to the other end of the first edge E1. The L-type assist pattern 102 is located between the L-type assist pattern 104 and the first edge E1. The layout pattern 100, the L-type assist pattern 102, and the L-type assist pattern 104 are separated from each other. The L-type assist pattern 102 surrounds the first edge E1 and the second edge E2. The L-type assist pattern 104 surrounds the first edge E1 and the third edge E3. Therefore, when the photomask structure 10 is used for the lithography process, the pattern fidelity of the lithography process may be improved. In this way, when the photomask structure 10 is used for the lithography process, the corner rounding of) the photoresist pattern formed by the lithography process may be effectively reduced, and the process window of the semiconductor manufacturing process and the reliability of the semiconductor device may be improved.

To sum up, in the photomask structure of the above embodiment, the end portion of the layout pattern includes a first edge, a second edge, and a third edge. The second edge is connected to one end of the first edge, and the third edge is connected to another end of the first edge. The first L-type assist pattern is located between the second L-type assist pattern and the first edge. The layout pattern, the first L-type assist pattern, and the second L-type assist pattern are separated from each other. The first L-type assist pattern surrounds the first edge and the second edge. The second L-type assist pattern surrounds the first edge and the third edge. Therefore, when the photomask structure of the above embodiment is used for the lithography process, the pattern fidelity of the lithography process may be improved. In this way, when the photomask structure of the above embodiment is used for the lithography process, the corner rounding of the photoresist pattern formed by the lithography process may be effectively reduced, and the process window of the semiconductor manufacturing process and the reliability of the semiconductor device may be improved.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A photomask structure, comprising:
a layout pattern, wherein an end portion of the layout pattern comprises a first edge, a second edge and a third edge, the second edge is connected to one end of the first edge, and the third edge is connected to another end of the first edge; and
a first L-type assist pattern and a second L-type assist pattern, wherein
the first L-type assist pattern is located between the second L-type assist pattern and the first edge,
the layout pattern, the first L-type assist pattern, and the second L-type assist pattern are separated from each other,
the first L-type assist pattern surrounds the first edge and the second edge, and
the second L-type assist pattern surrounds the first edge and the third edge.

2. The photomask structure according to claim 1, wherein
the first L-type assist pattern comprises a fourth edge and a fifth edge opposite to each other,
the fourth edge is adjacent to the second edge,
the fifth edge is adjacent to the third edge,
the second L-type assist pattern comprises a sixth edge and a seventh edge opposite to each other,
the sixth edge is adjacent to the second edge, and
the seventh edge is adjacent to the third edge.

3. The photomask structure according to claim 2, wherein the fourth edge is flush with the sixth edge.

4. The photomask structure according to claim 2, wherein the fifth edge is flush with the third edge.

5. The photomask structure according to claim 1, wherein
the first L-type assist pattern comprises:
a first main portion, located on one side of the first edge; and
a first extension portion, connected to one end of the first main portion and located on one side of the second edge, and
the second L-type assist pattern comprises:
a second main portion, located on one side of the first edge, wherein the first main portion is located between the second main portion and the first edge; and
a second extension portion, connected to one end of the second main portion and located on one side of the third edge.

6. The photomask structure according to claim 5, wherein a width of the first main portion and a width of the second main portion is the same.

7. The photomask structure according to claim 5, wherein a width of the first main portion and a width of the second main portion is different.

8. The photomask structure according to claim 5, wherein a width of the first extension portion and a width of the second extension portion is the same.

9. The photomask structure according to claim 5, wherein a width of the first extension portion and a width of the second extension portion is different.

10. The photomask structure according to claim 5, wherein a width of the first main portion and a width of the first extension portion is the same.

11. The photomask structure according to claim 5, wherein a width of the first main portion and a width of the first extension portion is different.

12. The photomask structure according to claim 5, wherein a width of the second main portion and a width of the second extension portion is the same.

13. The photomask structure according to claim 5, wherein a width of the second main portion and a width of the second extension portion is different.

14. The photomask structure according to claim 5, wherein
the layout pattern extends in a first direction,
the first edge is perpendicular to the first direction, and
the second edge and the third edge are parallel to the first direction.

15. The photomask structure according to claim 14, wherein
the first main portion extends in a second direction, and
the second direction is perpendicular to the first direction.

16. The photomask structure according to claim 14, wherein
the first extension portion extends in a second direction, and
the second direction is parallel to the first direction.

17. The photomask structure according to claim 14, wherein
the second main portion extends in a second direction, and
the second direction is perpendicular to the first direction.

18. The photomask structure according to claim 14, wherein
the second extension portion extends in a second direction, and
the second direction is parallel to the first direction.

19. The photomask structure according to claim 1, wherein
a minimum spacing between the first L-type assist pattern and the layout pattern is greater than or equal to a minimum spacing specified by a design rule, and
a minimum spacing between the second L-type assist pattern and the layout pattern is greater than or equal to the minimum spacing specified by the design rule.

20. The photomask structure according to claim 1, wherein a minimum spacing between the first L-type assist pattern and the second L-type assist pattern is greater than or equal to a minimum spacing specified by a design rule.
